(19) United States
(12) Patent Application Publication
(10) Pub. No.: US 2013/0243946 A1
(43) Pub. Date: Sep. 19, 2013

(54) THERMOELECTRIC CONVERTER ELEMENT AND CONDUCTIVE MEMBER FOR THERMOELECTRIC CONVERTER ELEMENT

(71) Applicant: UNIVERSAL ENTERTAINMENT CORPORATION, Tokyo (JP)

(72) Inventor: Koh Takahashi, Tokyo (JP)

(73) Assignee: Universal Entertainment Corporation, Tokyo (JP)

(21) Appl. No.: 13/886,531

(22) Filed: May 3, 2013

Related U.S. Application Data
(63) Continuation of application No. 12/995,408, filed on Nov. 30, 2010.

(51) Int. Cl. H01L 35/34; C23C 14/35

(52) U.S. Cl. CPC H01L 35/34; C23C 14/35
USPC 427/126.1; 204/192.15

(57) ABSTRACT

Disclosed is a low-cost thermoelectric converter element which is not decreased in electrical conductivity and thermal conductivity even under high temperature conditions. Specifically disclosed is a thermoelectric converter element (10) which is characterized by comprising a single element composed of a sintered cell (15) and a pair of electrodes (14) respectively attached to a heating surface which is one surface of the sintered cell (15) and a cooling surface which is a surface opposite to the heating surface, a conductive member (11) for electrical connection with an electrode other than the electrodes (14), and a metal layer (12) composed of at least one of gold and platinum. The thermoelectric converter element (10) is also characterized in that an electrode (14) of the single element is electrically connected with the conductive member (11) through the metal layer (12).

### TECHNICAL FIELD

The present invention relates to a thermoelectric conversion element, and particularly relates to a thermoelectric conversion element having superior electrical conductivity and heat conductivity, and a conductive member for a thermoelectric conversion element used in the manufacture of this thermoelectric conversion element.

### BACKGROUND ART

Thermoelectric conversion indicates mutually converting heat energy and electric energy using the Seebeck effect and Peltier effect. If using thermoelectric conversion, it is possible to produce electric power from heat flow using the Seebeck effect. Furthermore, it is possible to bring about a cooling phenomenon by way of heat absorption by flowing electric current in a material using the Peltier effect. This thermoelectric conversion does not cause excess waste product to be emitted during energy conversion due to being direct conversion. Furthermore, it has various benefits in that equipment inspection and the like is not required since moving devices such as motors and turbines are not required, and thus has received attention as a high efficiency application technology of energy.

In thermoelectric conversion, normally an element of metal or a semiconductor called a thermoelectric conversion element is used. The performance of these thermoelectric conversion elements (e.g., conversion efficiency) depends on the shape and material properties of the thermoelectric conversion element, and various considerations have been taken to improve the performance.

For example, as a thermoelectric conversion element used in a thermoelectric conversion module, one configured by connecting a number of p-type semiconductors and n-type semiconductors alternately in series has been proposed (e.g., refer to Patent Document 1). Generally, a semiconductor such as a Bi—Te system or Si—Ge system is used as the material of these thermoelectric conversion elements. Then, a semiconductor such as a Bi—Te system has been made in an attempt to exhibit thermoelectric properties that excel around room temperature and in an intermediate temperature range of 300° C. to 500° C.

However, the semiconductor such as a Bi—Te system has low heat resistance (high temperature stability) in the high temperature range, and thus application in the high temperature range is difficult. In addition, due to containing rare elements that are high cost and toxic (e.g., Te, Ge, etc.) semiconductors such as a Bi—Te system have problems in that the production cost is high and the environmental burden is great.

Consequently, the present inventors have previously proposed a single element thermoelectric conversion element module configured by a single thermoelectric conversion element and lead wires in order to avoid use of a semiconductor such as a Bi—Te system containing rare elements that are high cost and toxic and to realize a cost reduction (e.g., Patent Document 2). This thermoelectric conversion element module is formed by connecting a plurality of single elements of the same raw material together on a substrate, and generates electricity by way of a temperature differential occurring between a heating face, which is defined as one face of a single element, and a cooling face, which is defined as an opposite side to this heating face. A configuration is employed in which a pair of electrodes made by calcining silver paste is formed on the heating face and cooling face of the single element, and an electrode on the heating face side and an electrode on the cooling face side which are adjacent are electrically connected by a conductive member such as a lead wire.

Patent Document 1: Japanese Unexamined Patent Application, Publication No. H1-179376

Patent Document 2: PCT International Publication No. WO05/124881

### DISCLOSURE OF THE INVENTION

### Problems to be Solved by the Invention

However, in the above-mentioned thermoelectric conversion element module disclosed in Patent Document 2, in a case of using low cost nickel metal or the like as the electrically conductive member, there has been a problem in that the electrical conductivity and heat conductivity decline under high temperature conditions. The decline in the electrical conductivity and thermal conductivity greatly influences the thermoelectric conversion efficiency of the thermoelectric conversion element, and thus is an important problem to be solved.

The present invention has been made taking into account the above-mentioned problem, and the object thereof is to provide a low cost thermoelectric conversion element for which the electrical conductivity and heat conductivity do not decline even under high temperature conditions, and an electrically conductive member for thermoelectric conversion elements used in the manufacture of this thermoelectric conversion element.

### Means for Solving the Problems

The present inventors have conducted extensive research to solve the above-mentioned problems. As a result thereof, it was found that the declines in the electrical conductivity and thermal conductivity under high temperature conditions is caused by an increase in contact resistance due to metal oxides generated at the interface between the electrode and conductive member, thereby arriving at completion of the present invention. More specifically, the present invention provides the following.

A thermoelectric conversion element according to a first aspect includes: a single element including a sintered body cell and a pair of electrodes attached to a heating face, which is defined as one face of the sintered body cell, and a cooling face, which is defined as a face on an opposite side to the heating face; a conductive member for electrically connecting with another electrode different from the electrodes; and a metallic layer containing at least one metal among gold and platinum, in which the electrodes of the single element and the conductive member are electrically connected via the metallic layer.

According to the thermoelectric conversion element as described in the first aspect, the electrodes of a single element and a conductive member are electrically connected via a metallic layer composed of at least one metal among gold and platinum. In other words, by interposing a metal layer between the electrode of the single element and the conductive member, it is possible to reduce the likelihood of oxides being generated by the conductive member reacting with oxygen in air. As a result, even in a case of having used a conductive member composed of a low cost metal such as nickel metal, the generation of metal oxides and the like can be suppressed, and an increase in the contact resistance at the interface can be curbed, a result of which declines in the electrical conductivity and thermal conductivity can be avoided.

According to a thermoelectric conversion element of a second aspect, in the thermoelectric conversion element as described in the first aspect, the conductive member contains nickel metal.

As described above, with the thermoelectric conversion element of the present invention, it is possible to use a conductive member composed of an inexpensive metal since oxidation of the metal surface constituting the conductive member can be suppressed by having a metallic layer interposed between the electrode of the single element and the conductive member. As a result, inexpensive nickel metal is suitably used. With this, it is possible to provide a thermoelectric conversion element that is low cost and for which the electrical conductivity and thermal conductivity do not decline, even under high temperature conditions.

According to a thermoelectric conversion element of a third aspect, the thermoelectric conversion element as described in the first or second aspect further includes: a conductive layer disposed between the electrode of the single element and the metallic layer, and made by calcining conductive paste in which particles of metal are dispersed.

According to the thermoelectric conversion element as described in the third aspect, a conductive layer formed from a conductive paste is used in the electrical connection of the electrode of the single element and the metallic layer. With this, it is possible to form a thermoelectric conversion element without causing the electrical conductivity and thermal conductivity to decline.

According to a thermoelectric conversion element of a fourth aspect, in the thermoelectric conversion element as described in the third aspect, at least one among Au particles and Ag particles are contained in the particles of metal.

According to the thermoelectric conversion element as described in the fourth aspect, a thermoelectric conversion element having high electrical conductivity and thermal conductivity is obtained by using at least any metal among Au and Ag, which are periodic table group 11 elements, as the particles of metal constituting the conductive paste.

According to a thermoelectric conversion element of a fifth aspect, in the thermoelectric conversion element as described in any one of the first to fourth aspects, the sintered body cell includes a sintered body of a complex metal oxide.

By using a sintered body of a complex metal oxide as the sintered body cell, as well as effectively obtaining the operational effect of the invention according to the above-mentioned first to fourth aspects, the thermoelectric conversion element as described in the fifth aspect can allow for the heat resistance and mechanical strength to be improved. In addition, since complex metal oxides are inexpensive, it is possible to provide a lower cost thermoelectric conversion element.

According to a thermoelectric conversion element of a sixth aspect, in the thermoelectric conversion element as described in the fifth aspect, the complex metal oxide contains an alkali earth metal, rare earth metal, and manganese.

The thermoelectric conversion element as described in the sixth aspect can allow for the heat resistance at high temperatures to be further improved by using a complex metal oxide in which an alkali earth metal, rare earth metal, and manganese are made constituent elements. It is preferable to use calcium as the alkali earth metal element, and preferable to use yttrium or lanthanum as the rare earth element. More specifically, a perovskite-type CaMnO₃ system complex oxide or the like is exemplified. The perovskite-type CaMnO₃ system complex oxide is more preferably one represented by the general formula Ca₍₁₋ₓ₎MₓMnO₃ (M is yttrium or lanthanum, and x is in the range of 0.001 to 0.05).

According to a thermoelectric conversion element of a seventh aspect, a conductive member for a thermoelectric conversion element used in manufacture of a thermoelectric conversion element as described in any one of the first to sixth aspect includes: nickel metal; and a metallic layer containing at least one metal among gold and platinum.

The conductive member for a thermoelectric conversion element as described in the seventh aspect has a metallic layer that is composed of nickel metal and at least one metal among gold and platinum. As a result, it is possible to provide a thermoelectric conversion element suitably used in the manufacture of a thermoelectric conversion element as described in any of the first to sixth aspects that is low cost and for which the electrical conductivity and thermal conductivity do not decline, even under high temperature conditions.

### Effects of the Invention

According to the present invention, it is possible to provide a low cost thermoelectric conversion element for which the electrical conductivity and thermal conductivity do not decline, even under high temperature conditions.

### BRIEF DESCRIPTION OF THE DRAWINGS

FIG. 1 is a schematic diagram of a thermoelectric conversion element 10 according to an embodiment of the present invention.

### EXPLANATION OF REFERENCE NUMERALS

10 thermoelectric conversion element

11 conductive member

12 metallic layer

13 conductive layer

14A, 14B electrodes

15 sintered body cell

### PREFERRED MODE FOR CARRYING OUT THE INVENTION

### Thermoelectric Conversion Element

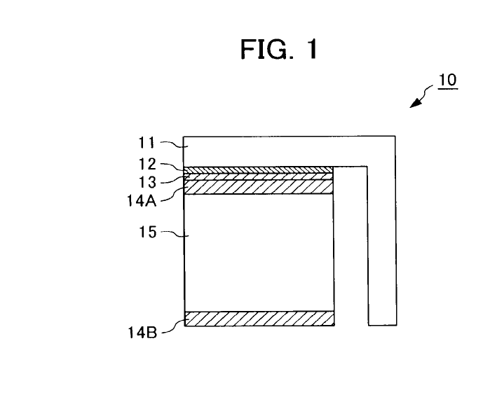

A schematic diagram of a thermoelectric conversion element 10 according to an embodiment of the present invention is shown in FIG. 1. As shown in FIG. 1, the thermoelectric conversion element 10 according to the present embodiment includes a single element composed of a sintered body cell 15, and a pair of electrodes 14A and 14B attached to a heating face, which is defined as one face of this sintered body cell 15, and a cooling face, which is defined as a face on an opposite side to the heating face. In addition, the thermoelectric conversion element 10 is provided with a conductive member 11 for electrically connecting with another electrode that is different from the pair of electrodes 14A and 14B, and a metallic layer 12 composed of at least one metal among gold and platinum, and the pair of electrodes 14A and 14B of the single element and the conductive member 11 are electrically connected via this metallic layer 12.

### Sintered Body Cell

The sintered body cell 15 used in the present embodiment is formed from a conventional well-known thermoelectric conversion material. As the thermoelectric conversion material, sintered bodies composed of a bismuth-tellurium compound, silica-germanium compound, complex metal oxide, or the like are exemplified. Among these, it is preferable to use a sintered body of a complex metal oxide that can cause heat resistance and mechanical strength to improve. In addition, since complex metal oxides are inexpensive, it is possible to provide a thermoelectric conversion element of lower cost.

Although the shape of the sintered body cell 15 is suitably selected to match the shape of the thermoelectric element 10 and a desired conversion efficiency, it is preferably a rectangular solid or a cube. For example, the size of the heating face and cooling face is preferably 5 to 20 mm×1 to 5 mm, and the height is preferably 5 to 20 mm.

A complex metal oxide containing an alkali earth metal, rare earth element, and manganese as constituent elements is preferably used as the complex metal oxide constituting the sintered body cell 15. According to such a complex metal oxide, a thermoelectric conversion element having high heat resistance and excelling in thermoelectric conversion efficiency is obtained. Above all, it is more preferable to use a complex metal oxide represented by the following general formula (I).

Ca₍₁₋ₓ₎MₓMnO₃ (1)

In formula (I), M is at least one element selected from among yttrium and lanthanoids, and x is a range of 0.001 to 0.05.

An example of a production method of the sintered body cell 15 composed of a complex metal oxide represented by the above general formula (I) will be explained. First, CaCO₃, MnCO₃, and Y₂O₃ are added into a mixing pot in which pulverizing balls have been placed, purified water is further added thereto, and the contents of the mixing pot are mixed by mounting this mixing pot to a vibrating ball mill and causing to vibrate for 1 to 5 hours. The mixture thus obtained is filtered and dried, and the dried mixture is preliminarily calcined in an electric furnace for 2 to 10 hours at 900 to 1100° C. The preliminarily calcined body thus obtained by preliminarily calcining is pulverized with a vibrating mill, and the ground product is filtered and dried. A binder is added to the ground product after drying, and then granulated by grading after drying. Thereafter, the granules thus obtained are molded in a press, and the compact thus obtained undergoes main calculation in an electric furnace for 2 to 10 hours at 1100 to 1300° C. From this, a CaMnO₃ system sintered body cell 15 represented by the above general formula (I) is obtained.

Herein, by holding the sintered body cell 15 with two copper plates and establishing a temperature differential of 5° C. between the upper and lower copper plates by heating the lower copper plate using a hot plate, the Seebeck coefficient a of the sintered body cell 15 obtained by the above-mentioned production method can be measured from the voltage generated between the upper and lower copper plates. In addition, the resistivity p can be measured by the four-terminal method using a digital volt meter.

For example, when measuring the Seebeck coefficient of the CaMnO₃ system sintered body cell 15 represented by the above general formula (I), a high value of at least 100 μV/K is obtained. It is preferable if x is within the range of 0.001 to 0.05 for the composition represented by the above general formula (I) as the thermoelectric conversion material, because values high for the Seebeck coefficient α and low for resistivity ρ will be obtained.

### Electrodes

The pair of electrodes 14A and 14B are respectively formed at the heating surface, which is defined as a face of one side of the sintered body cell 15, and the cooling face, which is defined as a face of an opposite side. Conventional well-known electrodes can be used as the pair of electrodes 14A and 14B without being particularly limited. For example, a copper electrode, composed of a metallic body to which a plating process has been performed or a ceramic plate to which a metallization process has been performed, is formed by electrically connecting to the sintered body cell 15 using solder or the like, for example, so that a temperature differential arises smoothly at both ends of the heating face and cooling face of the sintered body cell 15.

Preferably, the pair of electrodes 14A and 14B is formed by a method of coating a conductive paste such as that described later on the heating face and cooling face of the sintered body cell 15, and sintering. The coating method is not particularly limited, and coating methods by a paint brush, roller, or spraying are exemplified, and a screen printing method or the like can also be applied. The calcining temperature when sintering is preferably 200° C. to 800° C., and more preferably 400° C. to 600° C. The calcining time is preferably 10 to 60 minutes, and more preferably 30 to 60 minutes. In addition, calcining preferably raises the temperature step-wise in order to avoid explosive boiling. The thickness of the electrodes formed in this way is preferably 1 μm to 10 μm, and more preferably 2 μm to 5 μm.

According to the above-mentioned method, the pair of electrodes 14A and 14B can be formed more thinly. In addition, since it is not necessary to use a binder or the like as is conventionally, a decline in the thermal conductivity and electrical conductivity can be avoided, and the thermoelectric conversion efficiency can be raised further. Furthermore, the structure of the thermoelectric conversion element 10 can be simplified by integrating the sintered body cell 15 with the pair of electrodes 14A and 14B.

### Metallic Layer

The thermoelectric conversion element 10 according to the present invention includes a metallic layer 12 composed of at least one metal among gold and platinum between the electrode 14A of the single element and the conductive member 11. Specifically, the metallic layer 12 is interposed between the electrode 14A of the single element and conductive member 11 to electrically connect the electrode 14A of the single element and conductive member 11, whereby it is possible to reduce the probability of the conductive element 11 reacting with oxygen in air to generate oxides. As a result, even in a case of using the conductive element 11 composed of an inexpensive metal such as nickel metal, the generation of metal oxides and the like can be suppressed, and can curb an increase in the contact resistance of the interface, a result of which it is possible to avoid declines in the electrical conductivity and thermal conductivity.

Although the thickness of the metallic layer 12 is not particularly limited, it is preferably within the range of 50 nm to 1000 nm, and more preferably within the range of 100 nm to 500 nm. If the thickness of the metallic layer 12 is at least 100 nm, the generation of oxides on the surface of the conductive member 11 can be more effectively suppressed, and by having the metallic layer 12 interposed, it is possible to suppress declines in electrical conductivity and thermal conductivity.

The formation method of the metallic layer 12 is not particularly limited, and formation can be performed by a conventional well-known metal thin-film formation method. For example, various sputtering methods, vacuum deposition methods, and the like are exemplified, and among these, magnetron sputtering is preferably employed. As in the present embodiment, for example, the metallic layer 12 can be formed on the surface of the conductive member 11 by the above-mentioned method, and the thermoelectric conversion element 10 can be obtained by joining the conductive member 11 having the metallic layer 12 and the aforementioned single element using a conductive paste.

As explained above, the thermoelectric conversion element 10 according to the present embodiment includes a conductive layer 13 between the metallic layer 12 and the electrode 14A due to being formed by joining the conductive member 11 having the metallic layer 12 and the single element by conductive paste.

For example, a paste containing (A) 70 to 92 parts by mass of particles (powder) of metal, (B) 7 to 15 parts by mass of water or an organic solvent, and (C) 1 to 15 parts by mass of an organic binder can be used as the conductive paste. Herein, as the particles of metal (A), a periodic group 11 element exhibiting high electrical conductivity is preferable, and it is more preferable to use at least any metal among gold and silver, and further preferable to use silver. The shape of the particles can be made into various shapes such as spherical, elliptical, columnar, scale-shaped, and fiber-shaped. The average particle size of the particles of metal is 1 nm to 100 nm, preferably 1 nm to 50 nm, and more preferably 1 nm to 10 nm. By using particles having such an average particle size, a thinner film can be formed, and a layer that is more precise and having high surface smoothness can be formed. In addition, the surface energy of particles having such a nano-sized average particle size exhibits a high value compared to the surface energy of grains in a bulk state. As a result, it becomes possible to carry out sinter formation at a far lower temperature than the melting point of the metal by itself, and thus the manufacturing process can be simplified.

In addition, dioxane, hexane, toluene, cyclohexanone, ethyl cellosolve, butyl cellosolve, butyl cellosolve acetate, butyl carbitol acetate, diethylene glycol diethyl ether, diacetone alcohol, terpineol, benzyl alcohol, diethyl phthalate, and the like are exemplified as the organic solvent (B). These can be used individually or by combining at least two thereof.

As the organic binder (C), that having a good thermolysis property is preferred, and cellulose derivatives such as methylcellulose, ethyl cellulose, and carboxymethyl cellulose; polyvinyl alcohols; polyvinyl pyrolidones; acrylic resins; vinyl acetate-acrylic ester copolymer; butyral resin derivatives such as polyvinyl butyral; alkyd resins such as phenol-modified alkyd resin and caster oil-derived fatty acid-modified alkyd resins; and the like are exemplified. These can be used individually or by combining at least two thereof. Among these, cellulose derivatives are preferably used, and ethyl cellulose is more preferably used. In addition, other additives such as glass frit, a dispersion stabilizer, an antifoaming agent, and a coupling agent can be blended as necessary.

The conductive paste can be produced by sufficiently mixing the aforementioned components (A) to (C) according to a usual method, then performing a kneading process by way of a dispersion mill, kneader, three-roll mill, pot mill, or the like, and subsequently decompressing and defoaming. The viscosity of the conductive paste is not particularly limited, and is appropriately adjusted to a desired viscosity for use.

### Conductive Member

A conventional well-known conductive member such as of gold, silver, copper or aluminum is used the conductive member 11, without being particularly limited; however, it is particularly preferable to used nickel, which is low cost and is a comparatively stable conductive member in a high temperature oxidizing atmosphere. As explained above, with the thermoelectric conversion element 10 according to the present embodiment, it is suitable to use nickel, which is low cost and comparatively stable in a high temperature oxidizing atmosphere due to being able to suppress oxidation of the surface of the conductive member 11 by having the metallic layer 12 interposed between the electrode 14A of the single element and the conductive member 11. With this, it is possible to provide the thermoelectric conversion element 10 that is low cost and for which the electrical conductivity and thermal conductivity do not decline or the decline is suppressed, even under high temperature conditions.

Since the conductive member 11 also has high thermal conductivity, it is preferable to make it difficult for heat to be conducted by making the cross-sectional area of the conductive member 11 small, in order to avoid conduction of heat. More specifically, the ratio of the area of the electrode 14A or 14B to the cross-sectional area of the conductive member 11 is preferably 50:1 to 500:1. If the cross-sectional area of the conductive member 11 is too large and outside of the above-mentioned range, heat will be conducted and the necessary heat differential will not be obtained, and if the cross-sectional area of the conductive member 11 is too small and outside the above-mentioned range, electric current will not be able to flow as well as the mechanical strength thereof being inferior.

It should be noted that, in the present embodiment, it is also possible to provide a conductive member having the aforementioned metallic layer on the surface as the conductive member for a thermoelectric conversion element. More specifically, it is possible to provide a conductive member for a thermoelectric conversion element composed of nickel metal, having a metallic layer containing at least one metal among gold and platinum on the surface. According to such a conductive member for a thermoelectric conversion element, it becomes possible to form a thermoelectric conversion element that is low cost and for which the electrical conductivity and thermal conductivity do not decline or the decline is suppressed, even under high temperature conditions.

### EXAMPLES

### Example 1

### Preparation of Single Element

Calcium carbonate, manganese carbonate, and yttrium oxide were weighed so as to make Ca/Mn/Y=0.9875/1.0/0.0125, and wet mixing was performed for 18 hours by way of a ball mill. Thereafter, filtration and drying was performed, and preliminary calcining was performed in air for 10 hours at 1000° C. After pulverizing, the preliminarily calcined powder thus obtained was molded by a single-axis press at a pressure of 1 t/cm². This was calcined in air for 5 hours at 1200° C. to obtain a Ca_{0.9875}Y_{0.0125}MnO₃ sintered body cell. The dimensions of this sintered body cell were approximately 8.3 mm×2.45 mm×8.3 mm thick.

Electrodes were formed by coating a silver nano-paste made by Harima Chemicals, Inc. (average particle size: 3 nm to 7 nm, viscosity: 50 to 200 Pa·s, solvent: 1-decanol (decyl alcohol)) on the top face and bottom face of this sintered body cell using a paint brush, and baking for 30 minutes at 600° C.

Preparation of Conductive Member having Gold Layer

A gold layer was formed on the surface of the conductive member (connector) composed of nickel metal by way of a magnetron sputtering method. The thickness of the gold layer was 100 nm.

### Preparation of Thermoelectric Conversion Element

A thermoelectric conversion element was obtained by joining a single element obtained as described above and a conductive member having a gold layer using conductive paste. As the conductive paste, the above-mentioned silver nano-paste made by Harima Chemicals, Inc. used during electrode formation was used, and joining was performed in a similar way by baking for 30 minutes at 600° C.

### Preparation of Thermoelectric Conversion Module

A thermoelectric conversion module was prepared by connecting twenty-four of the thermoelectric conversion elements obtained as described above in series by conductive members having the above-mentioned gold layer.

### Comparative Example 1

A thermoelectric conversion element and thermoelectric conversion element module were prepared by a method similar to Example 1, except for not having the gold layer in Example 1 provided.

### Measurement of Electrical Properties

The electrical properties of the thermoelectric conversion element modules obtained in Example 1 and Comparative Example 1 were evaluated. More specifically, evaluation was conducted by performing measurement of the module resistance value before and after electrical power generation testing. The evaluation results are shown in Table 1.

It should be noted that, in the electrical power generation testing, a temperature differential was established in the module by heating the high temperature side using a hot plate set to 540° C. and cooling the low temperature side using a water-cooled heat sink, and the electrical power output was calculated from the open voltage and short-circuit current at this time. Although the open voltage reached 1.46 V in both Example 1 and Comparative Example 1, the short-circuit current was 632 mA in Example 1, and 535 mA in Comparative Example 1.

TABLE 1

| | Before electric power | After electric power |
|---|---|---|
| | generation testing | generation testing |
| Example 1 | 1.57Ω | 2.16Ω |
| (with gold layer) | | |
| Comparative Example 1 | 1.65Ω | 2.60Ω |
| (without gold layer) | | |

As shown in Table 1, it has been confirmed that, according to the present example including a gold layer between the electrode and conductive member (nickel metal), an increase in the module resistance value after electrical power generation testing could be suppressed compared to the Comparative Example not provided with a gold layer.

What is claimed is:

1. A method of manufacturing a thermoelectric conversion element including a single member, a conductive member, and a conductive layer,
the single member including a rectangular cuboid or cubic sintered body cell having a heating surface and a cooling surface opposite the heating surface, a first electrode on the heating surface, and a second electrode on the cooling surface,
the conductive member configured to be connected to a third electrode, including nickel, and a ratio of an area of each of the first electrode and the second electrode to a cross-sectional area of the conductive member from about 50:1 to about 500:1,
the conductive layer including at least one of gold and platinum, and provided at the conductive layer,
the method comprising:
(A) sintering a first conductive paste on the heating surface and the cooling surface of the sintered body cell to form the first electrode and the second electrode, thereby forming the single member;
(B) forming the conductive layer on a surface of the conductive member by sputtering or vacuum evaporation; and
(C) sintering a second conductive paste including metal particles, a solvent including an organic solvent or water, and an organic binder to combine the conductive layer on the surface of the conductive member and one of the first electrode and the second electrode.

2. The method of claim 1, wherein the sintered body cell comprises a sintered body of a complex metal oxide.

3. The method of claim 2, wherein the complex metal oxide comprises an alkali earth metal, a rare earth metal, and manganese.
